(19) United States
(12) Patent Application Publication
(10) Pub. No.: US 2014/0052393 A1
(43) Pub. Date: Feb. 20, 2014

(54) METHOD FOR DETERMINING SPATIAL LOCATION OF CONDUCTING WIRE AND AERIAL EARTH WIRE OF POWER TRANSMISSION LINE

(71) Applicants: Zhen Tang, Shanxi (CN); Kanging Wang, Shanxi (CN); Yujun Jia, Shanxi (CN); Jianguo Xu, Shanxi (CN); Yuewen Qi, Shanxic (CN); Xuezhi Wan, Shanxi (CN); Honglong Guo, Shanxi (CN); Shikai Wei, Shanxi (CN); Meisheng Chang, Shanxi (CN); Xingyong Zhao, Shanxi (CN); Jianhua Lian, Shanxi (CN); Yong Mi, Shanxi (CN); Kangmin Mi, Shanxi (CN); Aixiang Feng, Shanxi (CN); Hua Yang, Shanxi (CN); Hau Wang, Shanxi (CN); Hongwei Wang, Shanxi (CN); Tianzheng Wang, Shanxi (CN)

(72) Inventors: Zhen Tang, Shanxi (CN); Kanging Wang, Shanxi (CN); Yujun Jia, Shanxi (CN); Jianguo Xu, Shanxi (CN); Yuewen Qi, Shanxic (CN); Xuezhi Wan, Shanxi (CN); Honglong Guo, Shanxi (CN); Shikai Wei, Shanxi (CN); Meisheng Chang, Shanxi (CN); Xingyong Zhao, Shanxi (CN); Jianhua Lian, Shanxi (CN); Yong Mi, Shanxi (CN); Kangmin Mi, Shanxi (CN); Aixiang Feng, Shanxi (CN); Hua Yang, Shanxi (CN); Hau Wang, Shanxi (CN); Hongwei Wang, Shanxi (CN); Tianzheng Wang, Shanxi (CN)

(73) Assignees: SHANXI ELECTRIC POWER RESEARCH INSTITUTE, Shanxi (CN); SHANXI ELECTRIC POWER COMPANY, Shanxi (CN)

(21) Appl. No.: 13/882,161

(22) PCT Filed: Aug. 29, 2011
(86) PCT No.: PCT/CN2011/001447

§ 371 Date: Apr. 26, 2013

(30) Foreign Application Priority Data
Apr. 29, 2011 (CN) 201110111007.7

(51) Int. Cl. G01V 3/38; G01R 31/08

(52) U.S. Cl. CPC G01V 3/38; G01R 31/08
USPC 702/59

(57) ABSTRACT

Disclosed is a method for determining the spatial location of a conducting wire and an aerial earth wire of a power transmission line, so as to solve the problem that the method in the prior art is not applicable to determining the spatial location of the conducting wire and the aerial earth wire of the conventional power transmission line with respect to lightning shielding failures. In the present invention, according to the physical locations of the conducting wires and aerial earth wires, the power transmission line shielding efficiency is calculated based on that the corresponding lightning shielding failure trip rate is zero when the exposure arc is zero, thus providing designing and operating units with a reliable analytical method for preventing lightning shielding failures, and meanwhile working out the shielding efficiency of the conducting wire of each phase more accurately, so as to analyze the structural relations between the aerial earth wires and conducting wires to determine the lightning protection effect of the whole power transmission line. The present invention provides a supplementary analytical method of the shielding efficiency of the existing power transmission lines.

### BACKGROUND

1. Field

This invention relates to methods for determining conducting wires and aerial earth wires of power transmission lines, and more particularly, to a method for determining spatial locations of conducting wires and aerial earth wires of power transmission lines capable of shielding lightning shielding failures.

2. Description of the Related Art

Lightning strike is one of the main reasons for causing trip power failure accidents in power transmission lines. Statistically, lightning hazards account for more than 50% of all accidents in power grid systems. Therefore, protection design against the lighting strike for power transmission lines is of great importance to safe and stable operation of power grid systems. Currently, the design and performance estimation of lightning shielding systems for power transmission lines in China are based on the DL/T620-1997, Overvoltage and Insulation Coordination of AC Electric Devices, of the Power Industry Standards of the People's Republic of China. The calculation of lightning shielding failure trip rates in the Power Industry Standards does not take into consideration the influences of the lightning discharging process, the magnitude of the lightning current and the ground elevation on the shielding efficiency, but uses an integrated averaging method empirically and according to small current test models, however, the method cannot reflect specific characteristics of the lines and cannot solve the problems of shielding failures and shielding failure trip rates being large. Being an electric geometry analytical method established on the concept of lightning distance, the traditional, typical electric geometry model takes into rather detailed consideration the process for lightning to strike the lines, introduces the viewpoint that the trip rate is associated with the lightning current amplitude, and takes such factors as structures of the lines and the lightning parameters on the trip rate into account, but the method is summarized from operational experiences acquired in protecting lines with relatively large angles and relatively low heights of masts, and fails to consider differences in lightnings that strike the ground, and the locations of the aerial earth wires and conducting wires, so the method is not applicable to the determination of aerial earth wires of conventional power transmission lines.

### SUMMARY

The method for determining spatial locations of conducting wires and aerial earth wires of power transmission lines proposed in the present invention provides a supplementary analytical method for the shielding efficiency of currently available power transmission lines in shielding lightning shielding failures.

The present invention solves the aforementioned technical problem by the following technical solution.

A method for determining spatial locations of conducting wires and aerial earth wires of power transmission lines, including the following steps:

the first step—when a tilt angle of a ground where an iron tower bearing power transmission lines locates is 0°, it is assumed that a first G point and a second G point on the iron tower are mounting positions of aerial earth wires, and that power transmission lines fixedly arranged on the iron tower are conducting wire A, conducting wire B, and conducting wire C, respectively, wherein conducting wire A and conducting wire C are located on two sides of the iron tower, and conducting wire B is located in the middle and shielded by conducting wire A, conducting wire C, and the iron tower;

the second step—a lightning current amplitude I is calculated according to the following formula:

U=IZ_{c}/2.2,

where

U is 50% of a discharge voltage of an insulator string,

Z_{c} is wave impedance of the conducting wire, and Z_{c}=400Ω;

the third step—a value of a shielding radius r is calculated according to the formula r=6.72×I^{0.8}_{;}

the fourth step—a coefficient k of a ratio of breakdown strengths in the case an aerial earth wire is struck by lightning and in the case the ground is struck by lightning varying with a mast height h is calculated, according to a height h of the iron tower, by the formula k=1.18−h/108.69, and hence kr is obtained;

the fifth step—a semicircular space s₂ with conducting wire A as a center and r as a radius is the space where conducting wire A attracts lightning strike; a semicircular space s₂′ with conducting wire C as a center and r as a radius is the space where conducting wire C attracts lightning strike; a semicircular space s₁ with the first G point of a first aerial earth wire on the iron tower as a center and r as a radius is the space where the first aerial earth wire attracts lightning strike; and a semicircular space s₁′ with the second G point of a second aerial earth wire on the iron tower as a center and r as a radius is the space where the second aerial earth wire attracts lightning strike;

the sixth step—central angles and arc lengths corresponding to exposure arcs of the conducting wires are determined: an intersection point of the space s₂ where conducting wire A attracts lightning strike and the neighboring space s₁ where the first G point of the first aerial earth wire attracts lightning strike is k₁, and an arc from point k₁ to an intersection point of the space s₂ where conducting wire A attracts lightning strike and a horizontal line with the distance kr to the ground is the exposure arc of conducting wire A, whereby a value of central angle φ₁ corresponding to the exposure arc of conducting wire A, i.e., a value of an exposure angle; an intersection point of the space s₂′ where conducting wire C attracts lightning strike and the neighboring space s₁′ where the second G point of the second aerial earth wire attracts lightning strike is k₁′, and an arc from point k₁′ to an intersection point of the space s₂′ where conducting wire C attracts lightning strike and a horizontal line with the distance kr to the ground is the exposure arc of conducting wire C, whereby is calculated a value of central angle φ₂ corresponding to the exposure arc of conducting wire C, i.e., a value of an exposure angle; then lengths of the exposure arcs can be calculated with the following formulae:

l_{A}=r*φ₁l_{C}=r*φ₂;

the seventh step—central angles φ₃, φ₄ with which two aerial earth wires attract lightning strike and arc lengths thereof are determined as follows: an intersection point of the space s₁ where the first G point of the first aerial earth wire attracts lightning strike and the space s₁′ where the second G point of the second aerial earth wire attracts lightning strike is O, point O is connected to the first G point, the first G point is connected to point k₁, and the resulting LOG k₁ is the central angle φ₃ with which the first aerial earth wire attracts lightning strike; point O is connected to the second G point, the second G point is connected to point k₁′, and the resulting ∠OG k₁′; is the central angle φ₄ with which the second aerial earth wire attracts lightning strike, whereby the arc lengths corresponding to the two central angles attracting lightning strike can be obtained as following:

l_{G}r*φ₃,l_{G}′r*φ₄; and

the eighth step—shielding efficiency η of each mast can be calculated with the following formula:

$$η = ( \frac{{l}_{G} + {l}_{G}^{′}}{{l}_{A} + {l}_{C} + {l}_{G} + {l}_{G}^{′}} ) \times 100 \%$$

when the calculated η≧90%, the mounting positions of the first G point and the second G point of the aerial earth wires are reasonable;

when the calculated η∠90%, the mounting positions of the first G point, the second G point of the aerial earth wires, or conducting wires should be adjusted until η≧90%.

The above is directed to single-circuit power transmission lines, and the same can be applied to double-circuit power transmission lines.

This method calculates the shielding efficiency of the power transmission line based on that the corresponding lightning shielding failure trip rate is zero when the exposure arc is zero according to the physical locations of the various conducting wires and aerial earth wires, and determines the locations of the aerial earth wires of the power transmission line, thereby enhancing the lighting prevention efficiency of the power transmission line. The present invention provides a supplementary analytical method of the shielding efficiency of the existing power transmission lines.

### BRIEF DESCRIPTION OF THE DRAWINGS

FIG. 1 is a schematic diagram illustrating the calculation of shielding efficiency of a single-circuit power transmission line when the tilt angle of the ground whereon the iron tower stands is 0° according to the present invention;

FIG. 2 is a schematic diagram illustrating the calculation of shielding efficiency of a single-circuit power transmission line when the tilt angle of the ground whereon the iron tower stands is not 0° according to the present invention; and

FIG. 3 is a schematic diagram illustrating the calculation of shielding efficiency of a double-circuit power transmission line of the same tower when the tilt angle of the ground is 0° according to the present invention.

### DETAILED DESCRIPTION

This method calculates the shielding efficiency of (single-circuit, double-circuit) power transmission lines according to the physical locations of the various conducting wires and aerial earth wires and based on that the corresponding shielding efficiency is 100% when the exposure arc length of the conducting wire is zero. The method is capable of providing designing and operating units with a reliable analytical method for preventing lightning shielding failures, and meanwhile working out the shielding efficiency of the conducting wire of each phase accurately, so as to analyze the structural relations between the aerial earth wires and the conducting wires and to determine the lightning protection effect of the whole power transmission line.

When lightning strikes a power transmission line, flashover may occur only when the overvoltage of the lightning is greater than 50% of the discharge voltage of an insulator string. Accordingly, the method calculates a shielding radius according to a striking distance formula with 50% of the discharge voltage of the insulator string, then calculates the exposure arcs and the shielding efficiency of the conducting wires of each mast according to the shielding radius, and further calculates the shielding efficiency of the whole power transmission line using weighted averaging method with the proportion of the various types of masts in the entire power transmission line. The specific calculation process is described as follows with the single-circuit power transmission line as an example.

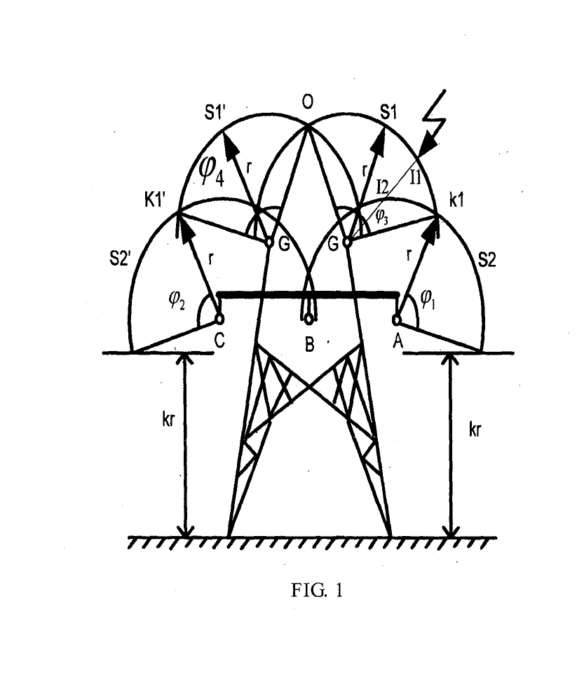

It is assumed that G is aerial earth wire, A, B and C are conducting wires, and conducting wire B is shielded by conducting wires A, C and the iron tower, therefore only conducting wires A, C are calculated, as shown in FIG. 1 showing structure view. As deemed in the Power Industry Standards, the voltage U on a conducting wire struck by lightning is approximately 100I. Z_{c} is wave impedance of the conducting wire, and is approximately 400Ω. Through observations and calculations, scientists of the former Soviet Union obtained I=5-30kA and the lightning channel wave impedance Z₀ as 900-600Ω. Out of stricter considerations, Z₀ is set as 900Ω, and formula (I) is derived following according to Peterson Rule:

$$U = I \times \frac{{Z}_{0} {Z}_{c}}{2 {Z}_{0} + {Z}_{c}} \qquad ( 1 )$$

E. R. Whitehead considered U=IZ_{c}/2.2, and U=IZ_{c}/2.2 is used in the calculation of this specification.

The striking distance formula is:

r=6.72×I^{0.8} (2)

in which r represents the shielding radius, and I represents the lightning current amplitude;

k=1.18−h/108.69 (3)

in which k represents a coefficient taking into consideration the ground field strength, and h represents the height of the iron tower.

Semicircular spaces s₁, s₂, s₁′, s₂′ with the r calculated above as a radius are spaces where lightning is attracted. This method considers the theory that the lightning precursor extends to the shortest distance G or straight line A upon arriving at the ranges of these attracting spaces. For instance, when the lightning precursor arrives at point I₁ in the range of the attracting space s₁ of an aerial earth wire, it is obvious that the lightning precursor is attracted by the closest first G point of the aerial earth wire, but in its way, the lightning precursor will also arrive at point I₂ in the range of the attracting space s₂ of conducting wire A, and whether the lightning first strikes the first G point or point A at that time depends upon whether the lightning is closer to the first G point or to point A—if the lightning is closer to point A, the lightning precursor will strike conducting wire A, which means the shielding fails.

The critical line of such shielding efficiency is calculated as follows. Since the tilt angle of the ground is zero and the two sides of the iron tower are symmetrical, taking the side of conducting wire A in FIG. 1 for example, circles of the first G point of the aerial earth wire and conducting wire A are drawn with spatial locations of the aerial earth wires and the conducting wires as centers, respectively and with the shielding radius r as radius, thus determining that the attracting spaces s₁, s₂ are crossed at an intersection point k₁. If the lightning precursor arrives at the left side of point k₁, although the lightning precursor will also arrive at the attracting range of the conducting wire later, it is closer to the first G point of the aerial earth wire than to conducting wire A, so it will first strike the aerial earth wire, thus the conducting wire can be protected from being struck by lightning. However, when the lightning precursor first arrives at the right side of point k₁, since the lightning precursor arrives at the position closer to conducting wire A than to the first G point of the aerial earth wire, it directly strikes conducting wire A, which means that shielding fails. If the lightning precursor arrives at none of attracting spaces s₁, s₂, it means that the lightning will strike the ground.

The shielding efficiency of the single-circuit power transmission line is as calculated as follows:

As regards the single-circuit power transmission line shown in FIG. 1, since its masts are bilateral symmetry, calculation of the shielding efficiency only requires the calculation of the angle corresponding to arc s₂, and the shielding efficiency of each mast can be calculated with the following formula:

$$η = ( \frac{{l}_{G} + {l}_{G}^{′}}{{l}_{A} + {l}_{C} + {l}_{G} + {l}_{G}^{′}} ) \times 100 \% .$$

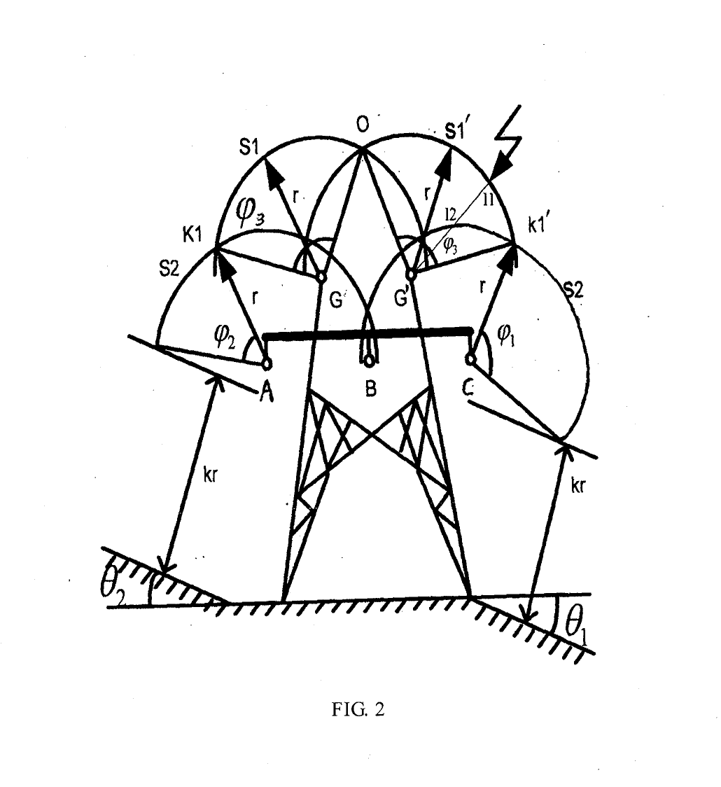

As regards the single-circuit power transmission line shown in FIG. 2, the shielding efficiency of each mast can be calculated with the following formula:

$$η = ( \frac{{l}_{G} + {l}_{G}^{′}}{{l}_{A} + {l}_{C} + {l}_{G} + {l}_{G}^{′}} ) \times 100 \% .$$

Calculation of the shielding efficiency of the double-circuit power transmission line of the same tower:

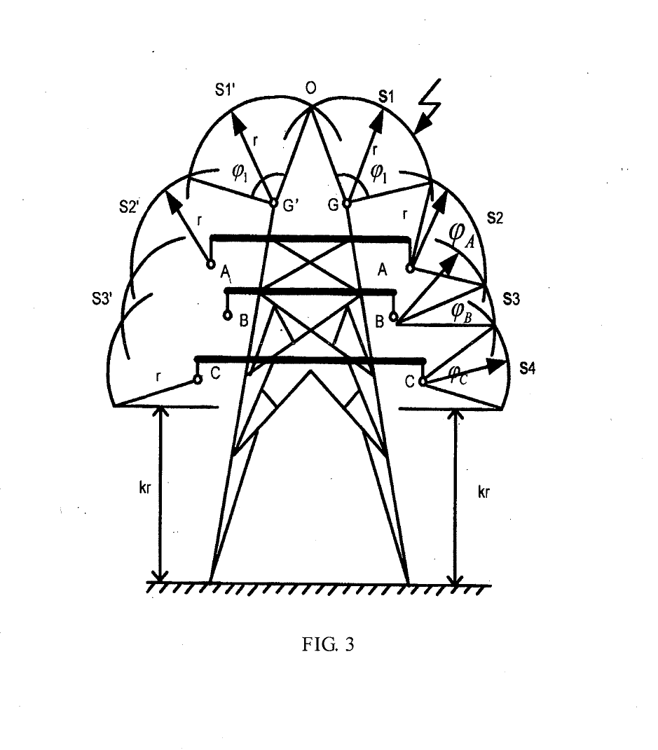

The principle of calculation of the shielding efficiency of the double-circuit power transmission line of the same tower is same as that of the calculation of the shielding efficiency of the single-circuit power transmission line, except that conducting wires A, B, C of the double-circuit power transmission line of the same tower are arranged at the two sides of the iron tower. Exposure arcs of conducting wires A, B, C should be entirely considered in the calculation. As exemplarily illustrated in FIG. 3, the specific calculation is as follows.

Since the structures at the two sides are identical when the tilt angle of the ground is zero (the principles of calculations are the same when the tilt angle of the ground is not zero, except that the exposed arc lengths at the two sides of the iron tower are different), the calculation formula is:

$$η = ( \frac{{l}_{G} + {l}_{G}^{′}}{{l}_{A} + {l}_{B} + {l}_{C} + {l}_{G} + {l}_{A}^{′} + {l}_{B}^{′} + {l}_{C}^{′} + {l}_{G}^{′}} ) \times 100 \%$$

Adjustment and Effects of Shielding Efficiency and Structure of the Iron Tower:

When the shielding efficiency of each mast is greater than 90%, it is considered that the shielding failure trip rate of the iron tower is very low, that the possibility for the lightning to strike the power transmission line is very small, and that operational requirements are met. When the shielding efficiency is smaller than 90%, it is necessary to adjust the structure of the iron tower (the spatial locations of the aerial earth wires or of the conducting wires can be adjusted), even the exposed arc lengths of conducting wires A, B, C, are increased, to increase their shielding efficiency until the requirements are met. As regards the shielding efficiency of the entire power transmission line, calculation can be performed by weighted averaging according to the weight of the same iron tower in the entire line, and the result should be greater than 90%. The calculation formula is as follows:

ηₑₙₜᵢᵣₑₗᵢₙₑ=\sqrt{(μ₁η₁)²+(μ₂η₂)²+ . . . +(μₙηₙ)₂}×100%

in which μₙ represents the weight of the n^{th} tower in the entire power transmission line; and

ηₙ represents the shielding efficiency of the n^{th} tower.

What is claimed is:

1. A method for determining spatial locations of conducting wires and aerial earth wires of power transmission lines, comprising the following steps:
the first step—when a tilt angle of a ground where an iron tower bearing power transmission lines locates is 0°, it is assumed that a first G point and a second G point on the iron tower are mounting positions of aerial earth wires, and that power transmission lines fixedly arranged on the iron tower are conducting wire A, conducting wire B, and conducting wire C, respectively, wherein conducting wire A and conducting wire C are located on two sides of the iron tower, and conducting wire B is located in the middle and shielded by conducting wire A, conducting wire C, and the iron tower;
the second step—a lightning current amplitude I is calculated according to the following formula:
U=IZ_{c}/2.2,
where
U is 50% of a discharge voltage of an insulator string,
Z_{c} is wave impedance of the conducting wire, and Z_{c}=400Ω;
the third step—a value of a shielding radius r is calculated according to the formula r=6.72×I^{0.8}
the fourth step—a coefficient k of a ratio of breakdown strengths in the case an aerial earth wire is struck by lightning and in the case the ground is struck by lightning varying with a mast height h is calculated, according to a height h of the iron tower, by the formula k=1.18−h/108.69 and hence kr is obtained;
the fifth step—a semicircular space s₂ with conducting wire A as a center and r as a radius is the space where conducting wire A attracts lightning strike; a semicircular space s₂′ with conducting wire C as a center and r as a radius is the space where conducting wire C attracts lightning strike; a semicircular space s₁ with the first G point of a first aerial earth wire on the iron tower as a center and r as a radius is the space where the first aerial earth wire attracts lightning strike; and a semicircular space s₁′ with the second G point of a second aerial earth wire on the iron tower as a center and r as a radius is the space where the second aerial earth wire attracts lightning strike;
the sixth step—central angles and arc lengths corresponding to exposure arcs of the conducting wires are determined: an intersection point of the space s₂ where conducting wire A attracts lightning strike and the neighboring space s₁ where the first G point of the first aerial earth wire attracts lightning strike is k₁, and an arc from point k₁ to an intersection point of the space s₂ where conducting wire A attracts lightning strike and a horizontal line with the distance kr to the ground is the exposure arc of conducting wire A, whereby a value of central angle φ₁ corresponding to the exposure arc of conducting wire A, i.e., a value of an exposure angle; an intersection point of the space s₂′ where conducting wire C attracts lightning strike and the neighboring space where the second G point of the second aerial earth wire attracts lightning strike is k₁′, and an arc from point k₁′ to an intersection point of the space s₂′ where conducting wire C attracts lightning strike and a horizontal line with the distance kr to the ground is the exposure arc of conducting wire C, whereby is calculated a value of central angle φ₂ corresponding to the exposure arc of conducting wire C, i.e., a value of an exposure angle; then lengths of the exposure arcs can be calculated with the following formulae:
l_{A}=r*φ₁l_{C}=r*φ₂;
the seventh step—central angles φ₃, φ₄ with which two aerial earth wires attract lightning strike and arc lengths thereof are determined as follows: an intersection point of the space s₁ where the first G point of the first aerial earth wire attracts lightning strike and the space s₁′ where the second G point of the second aerial earth wire attracts lightning strike is O, point O is connected to the first G point, the first G point is connected to point k₁, and the resulting ∠OGk₁ is the central angle φ₃ with which the first aerial earth wire attracts lightning strike; point O is connected to the second G point, the second G point is connected to point k₁′, and the resulting ∠OGk₁′; is the central angle φ₄ with which the second aerial earth wire attracts lightning strike, whereby the arc lengths corresponding to the two central angles attracting lightning strike can be obtained as following:
l_{G}=r*φ₃,l_{G}′=r*φ₄; and
the eighth step—shielding efficiency η of each mast can be calculated with the following formula:
$$η = ( \frac{{l}_{G} + {l}_{G}^{′}}{{l}_{A} + {l}_{C} + {l}_{G} + {l}_{G}^{′}} ) \times 100 \%$$
when the calculated η≧90%, the mounting positions of the first G point and the second G point of the aerial earth wires are reasonable;
when the calculated η∠90%, the mounting positions of the first G point, the second G point of the aerial earth wires, or conducting wires should be adjusted until η≧90%.
